(19) United States
(12) Patent Application Publication
(10) Pub. No.: US 2005/0044461 A1
(43) Pub. Date: Feb. 24, 2005

(54) Semiconductor device test circuit and semiconductor device

(75) Inventors: Akimitsu Ikeda, Kawasaki (JP); Naoaki Naka, Kawasaki (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/809,888

(22) Filed: Mar. 26, 2004

(30) Foreign Application Priority Data
Aug. 21, 2003 (JP) 2003-297210

(51) Int. Cl. G01R 31/28

(52) U.S. Cl. 714/729; 714/715

(57) ABSTRACT

A semiconductor device test circuit that prevents unnecessary data from being inputted to a functional macro circuit at the time of testing the functional macro circuit. In a plurality of flip-flops connected in series, serial test pattern data latched by a flip-flop at a stage is latched by a flip-flop at the next stage in synchronization with a first clock signal. The test pattern data latched by flip-flops at all the stages is outputted to the functional macro circuit at once in synchronization with a second clock signal inputted to the flip-flops.

### CROSS-REFERENCE TO RELATED APPLICATIONS

This application is based upon and claims priority of Japanese Patent Application No. 2003-297210, filed on Aug. 21, 2003, the contents being incorporated herein by reference.

### BACKGROUND OF THE INVENTION

(1) Field of the Invention

This invention relates to a semiconductor device test circuit and a semiconductor device and, more particularly, to a semiconductor device test circuit for testing a functional macro circuit and a semiconductor device including a plurality of functional macro circuits.

(2) Description of the Related Art

In recent years the integration level of semiconductor devices has risen. So far system on a chip (SOC) products fabricated by integrating a central processing unit (CPU), memories including a random access memory (RAM) and a read only memory (ROM), and other functions onto one chip ina semiconductor device, suchasanapplicationspecificintegratedcircuit (ASIC), have been put to practical use.

Such semiconductor devices include a plurality of hard macro circuits (functional macro circuits) according to functions and a logical circuit (user logic) including a sequential circuit for performing, for example, an operation process with the functional macro circuits. In addition, when some of these semiconductor devices are designed, a test for functional macro circuits is taken into consideration.

To test a functional macro circuit in a semiconductor device, data must be inputted to each terminal with timing according to a designer's plans and the state of a terminal must be measured with timing according to the plans. If not all the terminals necessary for a test are located on the semiconductor device, the following methods, for example, have been used.

In the first method, test pattern data for a test is inputted by connecting terminals connected to the functional macro circuit with input and output terminals on the semiconductor device via, for example, a selector.

In the second method, a master-slave latch circuit is located before the functional macro circuit. During normal operation of the functional macro circuit, the master-slave latch circuit is in through mode in which input data is outputted to the functional macro circuit in its original condition. When the functional macro circuit is tested, test pattern data latched by the latch circuit is outputted to the functional macro circuit (see, for example, Japanese Unexamined Patent Publication No. Hei4-186177, FIG. 1).

In these methods, however, even if the number of functional macro circuits included in the semiconductor device or the number of terminals for each functional macro circuit increases, it cannot exceed the upper limit of the number of terminals on the semiconductor device.

On the other hand, using a scan flip-flop circuit (SFF circuit) in a user logic has been proposed as a method capable of reducing the number of terminals to which test pattern data is inputted. A circuit for performing a test by conducting not only individual checks but also scan path checks on functional macro circuits is disclosed in Japanese Unexamined Patent Publication No. 2001-208810, paragraph nos. [0037]-[0071] and FIG. 1).

FIG. 3 is a rough circuit diagram of a conventional semiconductor device test circuit using conventional SFF circuits.

FIG. 4 is a circuit diagram showing the structure of the SFF circuits.

For the sake of simplicity a semiconductor device test circuit shown in FIG. 3 inputs test pattern data to a functional macro circuit 200 having four input terminals. This semiconductor device test circuit includes four SFF circuits 210, 211, 212, and 213. The SFF circuits 210, 211, 212, and 213 are connected in series. Each of the SFF circuits 210, 211, 212, and 213 has a terminal D where a signal is inputted from a user logic, a terminal SI where test pattern data is inputted, a terminal SM where a control signal for selecting the signal from the user logic or the test pattern data signal by a selector 210a shown in FIG. 4 as a signal to be inputted to the functional macro circuit 200 is inputted, a terminal CKwhere a clock signal is inputted, two terminals Q and SO as output ports, anda terminal RST for resetting.

In the SFF circuit 210 at the first stage in this semiconductor device test circuit, when a signal inputted from the terminal SI is selected by the selector 210a on the basis of a control signal inputted from the terminal SM, test pattern dataseriallyinputtedfromtheterminalSIislatchedbyadelayed flip-flop 210b in synchronization with a clock signal inputted from the terminal CK and is outputted from the terminals SO and Q. The signal outputted from the terminal SO of the SFF circuit 210 at the first stage is inputted to the terminal SI of the SFF circuit 211 at the second stage and is latched in synchronization with the next clock signal and is outputted from the terminals SO and Q of the SFF circuit 211 at the second stage. Similarly, the signal outputted from the terminal SO of the SFF circuit 211 at the second stage is inputted to the SFF circuits 212 and 213 in order. The test pattern data serially inputted in this way is eventually inputted in parallel from the terminals Q of the SFF circuits 210, 211, 212, and 213 to the functional macro circuit 200.

If test pattern data is inputted by the use of such SFF circuits, only one test pattern data input terminal is required for each functional macro circuit. Accordingly, the number of terminals for each functional macro circuit can be increased.

### SUMMARY OF THE INVENTION

A semiconductor device test circuit for testing a functional macro circuit is provided. This semiconductor device test circuit comprises a plurality of first flip-flop circuits connected in series so that serial test pattern data latched at a stage will be latched at the next stage in synchronization with a first clock signal and a plurality of second flip-flop circuits for outputting the test pattern data latched by the plurality of first flip-flop circuits to the functional macro circuit in synchronization with a second clock signal.

Furthermore, a semiconductor device comprising a plurality of functional macro circuits; a plurality of semiconductor device test circuits each including a plurality of first flip-flop circuits connected in series so that serial test pattern data latched at a stage will be latched at the next stage in synchronization with a first clock signal, and a plurality of second flip-flop circuits for outputting the test pattern data latched by the plurality of first flip-flop circuits to the corresponding functional macro circuit in synchronization with a second clock signal; a plurality of third flip-flop circuits, the number of the plurality of third flip-flop circuits depending on the number of the plurality of semiconductor device test circuits, connected in series for outputting a control signal for specifying the plurality of semiconductor device test circuits in synchronization with a third clock signal; a first selector circuit for selecting one of the plurality of semiconductor device test circuits to which the first clock signal is to be inputted in accordance with the control signal; a second selector circuit for selecting one of the plurality of semiconductor device test circuits to which the second clock signal is to be inputted in accordance with the control signal; and a third selector circuit for selecting one of signals outputted from the plurality of semiconductor device test circuits in accordance with the control signal is provided.

The above and other features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a circuit diagram showing the structure of a semiconductor device test circuit according to an embodiment of the present invention.

FIG. 2 is a circuit diagram of a semiconductor device including a control circuit for controlling the semiconductor device test circuit according to the embodiment of the present invention.

FIG. 3 is a circuit diagram of a conventional semiconductor device test circuit using conventional SFF circuits.

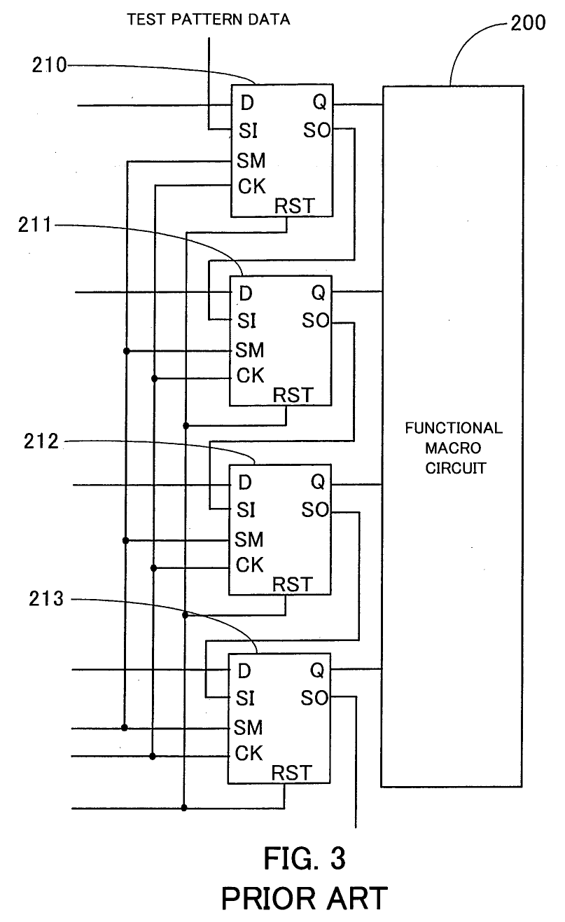

FIG. 4 is a circuit diagram showing the structure of the SFF circuits.

### DESCRIPTION OF THE PREFERRED EMBODIMENTS

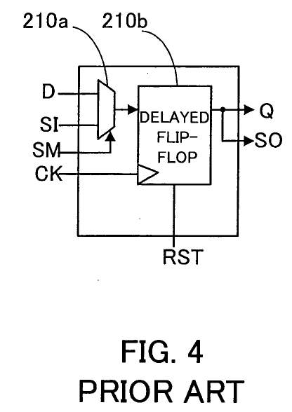

However, when test pattern data is inputted by the use of the conventional SFF circuits, the test pattern data inputted from the terminal SI is outputted from the terminals SO and Q because of the specifications for the SFF circuits shown in FIG. 4. In this case, unnecessary data will be outputted from the terminal Q of each SFF circuit at the time of shifting the test pattern data serially inputted from the terminal SI. As a result, the test pattern data cannot be inputted according to a designer's plans.

The present invention was made under the background circumstances described above. An object of the present invention is to provide a semiconductor device test circuit and semiconductor device capable of inputting test pattern data suitable for testing a functional macro circuit.

Embodiments of the present invention will now be described in detail with reference to the drawings.

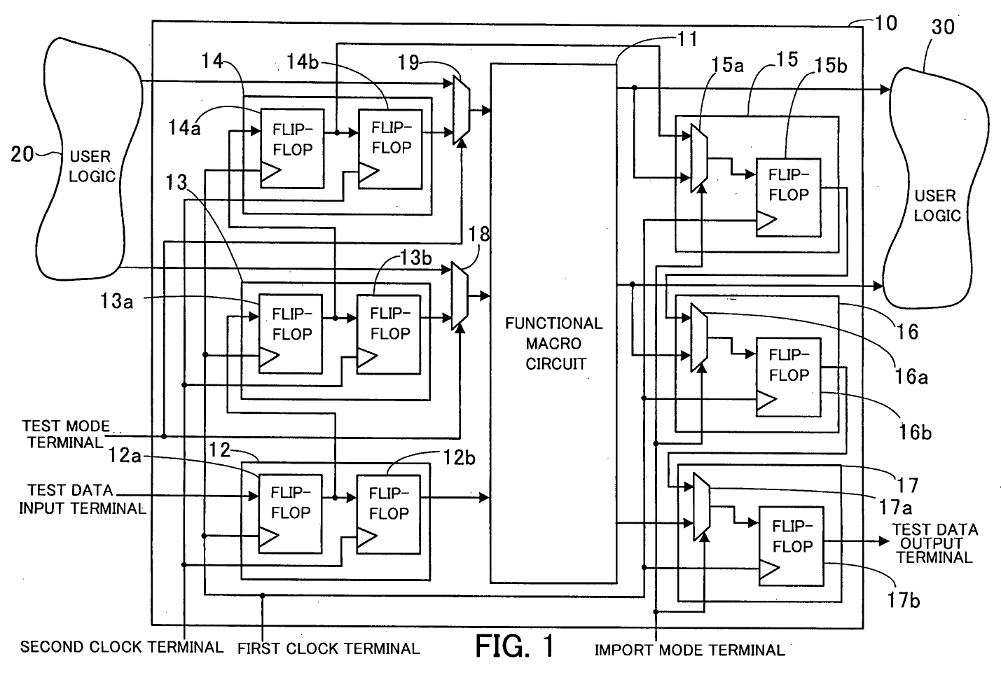

FIG. 1 is a circuit diagram showing the structure of a semiconductor device test circuit according to an embodiment of the present invention.

For the sake of simplicity a functional macro circuit 11 having three input terminals and three output terminals is shown in FIG. 1.

A semiconductor device test circuit 10 used for testing the functional macro circuit 11 comprises flip-flop circuits (hereinafter, simply referred to as flip-flops) 12a, 13a, and 14a for latching test pattern data (hereinafter, simply referred toas atest pattern) in synchronization with a first clock signal inputted to an external first clock terminal (not shown) and flip-flops 12b, 13b, and 14b for outputting the test pattern latched by the flip-flops 12a, 13a, and 14a, respectively, in synchronization with a second clock signal inputted to an external second clock terminal (not shown).

The test pattern inputted from an external test data input terminal (not shown) is inputted to the flip-flop 12a at the first stage.

The flip-flops 12a, 13a, and 14a, being delayed ones, are connected in series so that the serial test pattern latched at a stage will be latched at the next stage in synchronization with the first clock signal. That is to say, the flip-flops 12a, 13a, and 14a a reconnected so that output from the flip-flop 12a at the first stage is inputted to the flip-flop 13a at the second stage and so that output from the flip-flop 13a is inputted to the flip-flop 14a at the third stage.

In addition, connections are made so that the output from the flip-flop 12a, the output from the flip-flop 13a, and output from the flip-flop 14a will be inputted to the flip-flops 12b, 13b, and 14b, respectively, which are delayed ones.

Hereinafter a circuit made up of the two flip-flops 12a and 12b, a circuit made up of the two flip-flops 13a and 13b, and a circuit made up of the two flip-flops 14a and 14b will be referred to as first modules 12, 13, and 14 respectively.

The semiconductor device test circuit 10 further comprises a selector circuit 18 for selecting, in accordance with a control signal inputted to an external test mode terminal (not shown), the test pattern outputted from the flip-flop 13b or a signal from a user logic 20 and outputting it to the functional macro circuit 11 and a selector circuit 19 for selecting, in accordance with the control signal inputted to the external test mode terminal (not shown), the test pattern outputted from the flip-flop 14b or the signal from the user logic 20 and outputting it to the functional macro circuit 11.

In FIG. 1, output from the first module 12 is inputted to the functional macro circuit 11 without passing through a selector circuit. A terminal of the functional macro circuit 11 where the output from the first module 12 is inputted cannot be used by a user and is used solely for a test.

On the other hand, second modules 15, 16, and 17 are located at the first, second, and third stages, respectively, on the output side of the functional macro circuit 11.

Each of the second modules 15, 16, and 17 is a circuit including one selector circuit and one flip-flop. That is to say, the second module 15 includes a selector circuit 15a and a flip-flop 15b, the second module 16 includes a selector circuit 16a and a flip-flop 16b, and the second module 17 includes a selector circuit 17a and a flip-flop 17b.

The test pattern outputted from the flip-flop 14a in the first module 14 at the third stage on the input side of the functional macro circuit 11 and a signal outputted from the functional macro circuit 11 are inputted to the selector circuit 15a in the second module 15 at the first stage. The selector circuit 15a selects the test pattern or the signal outputted from the functional macro circuit 11 in accordance with a control signal inputted to an external import mode terminal (not shown) on the semiconductor device test circuit 10 and inputs it to the flip-flop 15b. The flip-flop 15b latches the test pattern or the signal outputted from the functional macro circuit 11 in synchronization with the first clock signal and outputs it to the second module 16 at the next stage.

The signal outputted from the flip-flop 15b at the first stage and a signal outputted from the functional macro circuit 11 are inputted to the selector circuit 16a in the second module 16. The selector circuit 16a selects the signal outputted from the flip-flop 15b at the first stage or the signal outputted from the functional macro circuit 11 in accordance with the control signal inputted to the external import mode terminal (not shown) on the semiconductor device test circuit 10 and inputs it to the flip-flop 16b. The flip-flop 16b imports the signal outputted from the flip-flop 15b at the first stage or the signal outputted from the functional macro circuit 11 in synchronization with the first clock signal and outputs it to the second module 17 at the next stage.

Similarly, the signal outputted from the flip-flop 16b at the second stage and a signal outputted from the functional macro circuit 11 are inputted to the selector circuit 17a in the second module 17 at the third stage. The selector circuit 17a selects one of these two signals in accordance with the control signal and inputs it to the flip-flop 17b. The flip-flop 17b latches the signal selected by the selector circuit 17a in synchronization with the first clock signal and outputs it to an external test data output terminal (not shown) on the semiconductor device test circuit 10.

The operation of the semiconductor device test circuit 10 will now be described.

First, normal operation performed with the user logic 20 and a user logic 30 will be described.

At normal operation time, the selector circuit 18 selects not the test pattern outputted from the first module 13 but the signal from the user logic 20 in accordance with the control signal and inputs it to the functional macro circuit 11. Similarly, the selector circuit 19 selects not the test pattern outputted from the first module 14 but the signal from the user logic 20 in accordance with the control signal and inputs it to the functional macro circuit 11. The functional macro circuit 11 performs predetermined operation according to the signals inputted thereto and outputs signals to the user logic 30 on the output side. The user logic 20 on the input side and the user logic 30 on the output side are shown separately in FIG. 1, but they may be the same.

Next, the operation of the semiconductor device test circuit 10 performed when the functional macro circuit 11 is tested will be described.

At test time, the selector circuit 18 selects not the signal from the user logic 20 but the test pattern outputted from the first module 13 in accordance with the control signal and inputs it to the functional macro circuit 11. In addition, the selector circuit 19 selects not the signal from the user logic 20 but the test pattern outputted from the first module 14 in accordance with the control signal and inputs it to the functional macro circuit 11.

When the test pattern is inputted serially from the test data input terminal (not shown) to the first module 12 at the first stage, the flip-flop 12a latches the leading bit of the test pattern in synchronization with a first clock signal. It is assumed that the test pattern is “110”. Then “1” in the leading bit is imported and latched by the flip-flop 12a in the first module 12 on the basis of an initial first clock signal. The test pattern is imported and latched by the flip-flop at the next stage, that is to say, by the flip-flop 13a in the first module 13 in synchronization with a second first clock signal. At this time “1” in the next bit is also latched by the flip-flop 12a in the first module 12 in synchronization with this first clock signal.

“1” in the test pattern latched by the flip-flop 13a in the first module 13 is latched by the flip-flop 14a in the first module 14 on the basis of a third first clock signal. At this time “0” in the last bit is latched by the flip-flop 12a in the first module 12 and “1” in the second bit is latched by the flip-flop 13a in the first module 13.

The test pattern serially inputted is shifted in this way by the flip-flops 12a, 13a, and 14a at the three stages connected in series. At this time the output from the flip-flops 12a, 13a, and 14a is inputted to the flip-flop 12b in the first module 12, the flip-flop 13b in the first module 13, and the flip-flop 14b in the first module 14, respectively. However, the flip-flops 12b, 13b, and 14b are in a state (in a low-level state, for example) in which a second clock signal for latching a signal is not inputted thereto. Accordingly, the signals outputted from the flip-flops 12a, 13a, and 14a to which the test pattern is inputted are not outputted from the first modules 12, 13, and 14.

When the entire test pattern has been inputted serially, the second clock signal is inputted (the flip-flops 12b, 13b, and 14b go into, for example, a high-level state). The flip-flops 12b, 13b, and 14b latch the test pattern outputted from the flip-flops 12a, 13a, and 14a, respectively, and input the test pattern to the functional macro circuit 11 in parallel in synchronization with the second clock signal.

As stated above, only when the second clock signal for uploading is inputted to the flip-flops 12b, 13b, and 14b, the test pattern is outputted from the first modules 12, 13, and 14. This prevents unnecessary data from being inputted to the functional macro circuit 11.

The test pattern outputted from the flip-flop 14a in the first module 14 at the last stage is inputted to the selector circuit 15a in the second module 15 at the first stage on the output side.

The operation of the second modules 15, 16, and 17 will now be described.

First, operation performed when the semiconductor device test circuit 10 is not in mode (import mode) in which it imports signals from the functional macro circuit 11 will be described.

When the control signal inputted from the import mode terminal (not shown) is at, for example, a low level and the semiconductor device test circuit 10 is not in import mode, the selector circuit 15a in the second module 15 at the first stage selects the serial test pattern outputted from the flip-flop 14a in the first module 14 at the last stage and inputs it to the flip-flop 15b.

The flip-flop 15b latches the inputted test pattern in synchronization with an initial first clock signal and inputs it to the selector circuit 16a in the second module 16 at the second stage. The selector circuit 16a in the second module 16 selects the test pattern outputted from the flip-flop 15b at the first stage on the basis of the control signal and inputs it to the flip-flop 16b. The flip-flop 16b latches the test pattern in synchronization with a second first clock signal. At this time the flip-flop 15b in the second module 15 at the first stage latches the second bit of the test pattern inputted serially in synchronization with the second first clock signal.

The test pattern latched by the flip-flop 16b in the second module 16 is inputted to the selector circuit 17a in the second module 17 at the last stage. The selector circuit 17a selects the test pattern outputted from the flip-flop 16b at the second stage on the basis of the control signal and inputs it to the flip-flop 17b. This is the same with the selector circuit 16a.

The flip-flop 17b latches the test pattern in synchronization with a third first clock signal inputted. At this time each of the flip-flop 15b at the first stage and the flip-flop 16b at the second stage latches the next bit of the test pattern.

Output from the flip-flop 17b is outputted to the test data output terminal (not shown). As a result, the test pattern inputted from the test data input terminal (not shown) is outputted serially in synchronization with the first clock signals.

Next, operation performed when the semiconductor device test circuit 10 is in import mode will be described.

In import mode, the control signal inputted from the import mode terminal (not shown) goes into, for example, a high level and each of the selector circuit 15a in the second module 15, the selector circuit 16a in the second module 16, and the selector circuit 17a in the second module 17 selects a signal outputted from the functional macro circuit 11. As a result, output signals from the functional macro circuit 11 corresponding to the inputted test pattern are inputted to the flip-flops 15b, 16b, and 17b in parallel. The output signals inputted to the flip-flops 15b, 16b, and 17b are latched by them in synchronization with a first clock signal. When the output signals are imported, the control signal goes into, for example, a low level and the import mode ends. Subsequently, the output signals latched by the flip-flop 15b in the second module 15, the flip-flop 16b in the second module 16, and the flip-flop 17b in the second module 17 are shifted in synchronization with a first clock signal. Finally, the output signals from the functional macro circuit 11 corresponding to the inputted test pattern are outputted from the flip-flop 17b at the last stage to the test data output terminal (not shown) as serial signals.

As a result, a designer etc. can judge by checking the outputted signals, for example, whether the functional macro circuit is functioning normally.

The above functional macro circuit 11 has the three input terminals and the three output terminals, but in practice some functional macro circuits have several hundred terminals. The above description will apply to these functional macro circuits.

That is to say, such functional macro circuits with many terminals must have only one test mode terminal where a test pattern is inputted and one test data output terminal. Furthermore, unlike the conventional method using SFF circuits, the semiconductor device test circuit according to the present invention can prevent unnecessary data from being inputted to the functional macro circuit 11.

In addition, it is not necessary that the above first or second modules should be connected to all the terminals of the functional macro circuit 11. The functional macro circuit 11 may have a terminal solely for directly inputting a signal from the user logic.

A semiconductor device including a control section for controlling the semiconductor device test circuit according to the embodiment of the present invention will now be described.

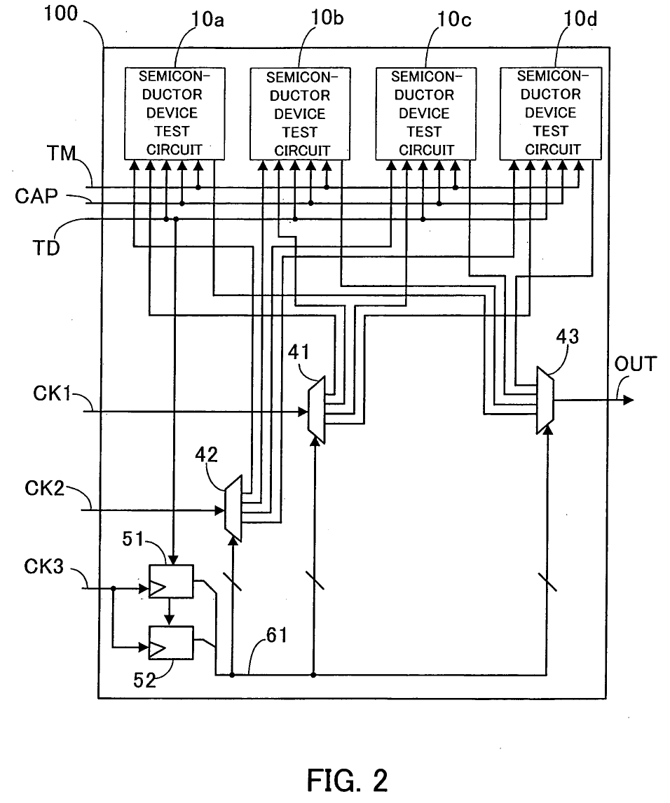

FIG. 2 is a circuit diagram of a semiconductor device including a control circuit for controlling the semiconductor device test circuit according to the embodiment of the present invention.

A semiconductor device 100 shown in FIG. 2 corresponds to, for example, a one-chip integrated circuit including a plurality of functional macro circuits.

The semiconductor device 100 shown in FIG. 2 includes four semiconductor device test circuits 10a, 10b, 10c, and 10d, like the one shown in FIG. 1, for testing the functional macro circuit 11. The user logics in FIG. 1 connected to the functional macro circuit 11 are not shown in FIG. 2.

A test mode terminal TM where a control signal is inputted, an import mode terminal CAP, and a test data input terminal TD where a test pattern or the like is inputted, like those described above, are connected to each of the semiconductor device test circuits 10a, 10b, 10c, and 10d. Moreover, selector circuits 41 and 42 for selecting one of the semiconductor device test circuits 10a, 10b, 10c, and 10d where the above first and second clock signals are to be inputted (from first and second clock terminals respectively) are included. A selector circuit 43 for selecting a signal outputted from one of the semiconductor device test circuits 10a, 10b, 10c, and 10d and for outputting it to a test data output terminal OUT is also included. In addition, two flip-flops 51 and 52 which output a signal for controlling the selector circuits 41, 42, and 43 are included. The flip-flops 51 and 52 are delayed flip-flop circuits.

The flip-flops 51 and 52 are connected in series. The flip-flop 51 at the first stage is connected to the test data input terminal TD. Output from the flip-flops 51 and 52 makes up a 2-bit signal and is inputted to the selector circuits 41, 42, and 43 via a signal line 61. The flip-flops 51 and 52 are also connected to a third clock terminal CK3 where a third clock signal is inputted.

In this semiconductor device 100, it is assumed that the signal “01” is inputted serially to the test data input terminal TD. Then this signal is latched by the flip-flops 51 and 52 in synchronization with the third clock signal. As a result, the selector circuits 41, 42, and 43 will select, for example, the second semiconductor device test circuit 10b. When the semiconductor device test circuit 10b to be selected is determined, the third clock signal goes into, for example, a low level so that the semiconductor device test circuit 10b selected will not be switched to another semiconductor device test circuit during a test. By doing so, the test is performed in the above way by the semiconductor device test circuit 10b with the test pattern continuously inputted to the test data input terminal TD at test time and a test result will be outputted from the test data output terminal OUT.

As stated above, with the above semiconductor device 100, a desired functional macro circuit can be selected properly from among the plurality of functional macro circuits and be tested. In addition, a terminal where a signal for specifying a functional macro circuit to be tested is inputted is also used as the test data input terminal TD where a test pattern is inputted, so the number of terminals can be reduced.

The semiconductor device 100 including the four semiconductor device test circuits 10a, 10b, 10c, and 10d (including four functional macro circuits) has been described. However, there is no limit to the number of semiconductor device test circuits included in the semiconductor device 100. For example, if the semiconductor device 100 includes not less than five, and not more than eight, semiconductor device test circuits, then three or more flip-flops which output a signal for controlling the above selector circuits 41, 42, and 43 should be located. That is to say, the number of flip-flops should be changed according to that of functional macro circuits.

The present invention is applicable to a test for a functional macro circuit included in an SOC product or the like in which a plurality of functions are integrated onto one chip.

With the semiconductor device test circuit according to the present invention, serial test pattern data inputted to and latched by the first flip-flop circuits is not outputted directly to a functional macro circuit but is outputted to the functional macro circuit in synchronization with a second clock signal inputted to the second flip-flops. This prevents unnecessary data from being inputted to the functional macro circuit.

Therefore, the functional macro circuit can be tested properly.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

1. A semiconductor device test circuit for testing a functional macro circuit, the circuit comprising:
a plurality of first flip-flop circuits connected in series so that serial test pattern data latched at a stage will be latched at the next stage in synchronization with a first clock signal; and
a plurality of second flip-flop circuits for outputting the test pattern data latched by the plurality of first flip-flop circuits to the functional macro circuit in synchronization with a second clock signal.

2. The semiconductor device test circuit according to claim 1, wherein the plurality of first flip-flop circuits and the plurality of second flip-flop circuits are delayed flip-flop circuits.

3. The semiconductor device test circuit according to claim 1, further comprising selector circuits for selecting the test pattern data outputted from each of the plurality of second flip-flop circuits or a signal from a user logic and outputting the selected test pattern data or the selected signal to the functional macro circuit in accordance with a control signal.

4. The semiconductor device test circuit according to claim 1, further comprising, a circuit including a selector circuit and a third flip-flop circuit, wherein a signal outputted from the functional macro circuit and the test pattern data outputted from the first flip-flop circuit at a last stage are inputted to the selector circuit at a first stage, while a signal outputted from the functional macro circuit and a signal outputted from the third flip-flop circuit at a preceding stage are inputted to the selector circuit at each of subsequent stages, further wherein the third flip-flop circuit latches a signal selected by the selector circuit in synchronization with the first clock signal.

5. The semiconductor device test circuit according to claim 4, wherein the third flip-flop circuit is a delayed flip-flop circuit.

6. The semiconductor device test circuit according to claim 4, wherein the third flip-flop circuit included in the circuit at a last stage serially outputs the test pattern data or the signal outputted from the functional macro circuit.

7. A semiconductor device comprising:
a plurality of functional macro circuits;
a plurality of semiconductor device test circuits each including:
a plurality of first flip-flop circuits connected in series so that serial test pattern data latched at a stage will be latched at the next stage in synchronization with a first clock signal, and
a plurality of second flip-flop circuits for outputting the test pattern data latched by the plurality of first flip-flop circuits to the corresponding functional macro circuit in synchronization with a second clock signal;
a plurality of third flip-flop circuits, the number of the plurality of third flip-flop circuits depending on the number of the plurality of semiconductor device test circuits, connected in series for outputting a control signal for specifying one of the plurality of semiconductor device test circuits in synchronization with a third clock signal;
a first selector circuit for selecting one of the plurality of semiconductor device test circuits to which the first clock signal is to be inputted in accordance with the control signal;
a second selector circuit for selecting one of the plurality of semiconductor device test circuits to which the second clock signal is to be inputted in accordance with the control signal; and
a third selector circuit for selecting one of signals outputted from the plurality of semiconductor device test circuits in accordance with the control signal.

8. The semiconductor device according to claim 7, wherein the signal for specifying the semiconductor device test circuit is inputted froma test data input terminal where the test pattern data is inputted to the third flip-flop circuit at a first stage.
